(19) United States
(12) Patent Application Publication
(10) Pub. No.: US 2006/0128149 A1
(43) Pub. Date: Jun. 15, 2006

(54) Method for forming a metal wiring in a semiconductor device

(75) Inventor: Hyoung Yoon Kim, Cheongju-si (KR)

Correspondence Address: THE LAW OFFICES OF ANDREW D. FORTNEY, PH.D., P.C., 7257 N. MAPLE AVENUE, BLDG. D, SUITE 107, FRESNO, CA, 93720, US

(73) Assignee: DongbuAnam Semiconductor Inc.

(21) Appl. No.: 11/304,276

(22) Filed: Dec. 13, 2005

(30) Foreign Application Priority Data
Dec. 15, 2004 (KR) 10-2004-0105969

(51) Int. Cl. H01L 21/465

(52) U.S. Cl. 438/669; 438/778; 438/710

(57) ABSTRACT

A method for forming a metal wiring in a semiconductor device is disclosed. The method comprises the steps of: forming an interlevel dielectric layer over a semiconductor substrate; forming a metal layer on an upper surface of the interlevel dielectric layer; forming a metal wiring including a plurality of metal lines by selectively etching the metal layer; and forming a metal-insulating layer by filling a gap between the plurality of metal lines with an insulative material, wherein filling the insulative material comprises (a) depositing the insulative material over and between the plurality of metal lines using a first high density plasma (HDP), (b) etching the deposited insulative material, and (c) depositing the insulative material in the gap using a second HDP.

This application claims the benefit of Korean Application No. 10-2004-0105969, filed on Dec. 15, 2004, which is hereby incorporated by reference herein in its entirety.

### BACKGROUND OF THE INVENTION

1. Field of the Invention

The present invention relates to semiconductor device manufacturing technology. More specifically, the present invention relates to a method for forming a metal wiring which electrically connects the unit devices formed on a semiconductor substrate.

2. Description of the Related Art

A variety of electronic products such as a computer, television and the like have been widely used. In general, these electronic products include an integrated circuit with semiconductor devices thereon such as a diode, transistor, and so on. Such semiconductor devices can be manufactured by one process for forming unit transistors or diodes in active regions (e.g., a so-called “front end” process), and another process for forming a metal wiring for electrically connecting unit devices with each other (e.g., a so-called “back end” process). The present invention involves the process for forming a metal wiring.

A conventional method for forming a metal wiring in a semiconductor device is described with reference to FIG. 1.

Referring to FIG. 1, a metal layer 20 is formed on an upper surface of an interlevel dielectric layer 10, as shown in step (a) of FIG. 1. A via or contact hole may be formed in the interlevel dielectric layer 10 in advance.

In view of the high integration of semiconductor devices, a multilayered wiring structure is advantageous rather than single layered wiring, which has a low degree of freedom in design. In a multilayered wiring structure, an interlevel dielectric layer insulates an upper metal wiring from a lower metal wiring. Here, an electrical connection between the upper metal wiring and the lower metal wiring may be made through vias or contacts formed in the interlevel dielectric layer. The metal layer 20 is used to form the upper metal wiring in successive processes. Tungsten (W) or aluminum (Al) is generally used as a material for the metal layer 20. The metal layer 20 can be formed by sputtering and the like. In addition, a barrier (not shown) can be formed between the interlevel dielectric layer 10 and the metal layer 20, comprising a single layer of titanium (Ti) or titanium nitride (TiN), or a bilayer of titanium (Ti) and titanium nitride (TiN).

Next, as shown in step (b) of FIG. 1, a plurality of metal lines 21 are formed by a photolithographic process. Specifically, a photoresist (not shown) is coated on the metal layer 20 and exposed in a predetermined pattern. Then, the exposed portion of the photoresist is removed so that a photoresist pattern is formed. Subsequently, the metal layer 20 is etched using the photoresist pattern as a mask. As a result, a metal wiring including the plurality of metal lines 21 is formed.

Finally, as shown in step (c) of FIG. 1, gaps between metal lines 21 are filled with an insulative material to form a metal-insulating layer 30. A portion of the insulative material over the metal lines 21 may be removed by a chemical and mechanical polishing (CMP) so that an upper surface of metal wiring (or metal-insulating layer 30) is planarized.

In a general multilevel-interconnection structure, an uneven surface topography of the uppermost layer becomes more prominent in proportion to an increase in the number of layers formed on the semiconductor substrate. The surface topography of the uppermost layer may be so uneven that it can have a fracture caused by protrusions or cracks. In order to avoid such defects, it is necessary to improve a degree of planarization of the metal-insulating layer. In general, filling gaps between the metal lines with a Spin-On-Grass (SOG) material has been used as one of solutions. However, the SOG material reduces a life span of semiconductor device. Alternatively, a high-density plasma (HDP) has been recently used as a method for forming the metal-insulating layer. In the HDP process, a processing gas, containing a source material of the metal-insulating layer, is injected into a chamber where a semiconductor substrate is placed. Here, high-energy electrons collide with neutral molecules of the processing gas so that the molecules are decomposed, reacted or otherwise made to become plasmatic. These plasmatic molecules are adsorbed on the semiconductor substrate so that the metal-insulating layer is deposited.

However, the above-explained HDP method may have a problem as illustrated in FIG. 2. Namely, as shown in FIG. 2, the insulative material 31 is rapidly deposited on the top corner of metal lines 21, while the insulative material 31 is slowly deposited in the bottom of metal lines 21 (i.e., on the upper surface of the interlevel dielectric layer 10). It is believed that a difference between frequencies for the insulative material 31 to contact with metal lines 21 in the top corner, the sidewall and the bottom of metal lines 21, respectively, may cause the differential deposition of insulative material 31 on the different surfaces. Owing to such a difference between depositing speeds, the top of the gap between metal lines 21 is closed by an overhang 31a, before the inside and the bottom of the gaps are sufficiently filled with the insulative material 31. As a result, voids may occur inside the gaps, which may result in formation of a bridge so that the yield of semiconductor devices from the wafer may decrease.

### SUMMARY OF TH INVENTION

It is, therefore, an object of the present invention to provide a method for forming a metal wiring in a semiconductor device, comprising the step of removing an overly deposited insulative material portion by an intermediate etching step between depositing steps using a high density plasma (HDP), thus preventing generation of a void due to a difference of depositing speeds.

To achieve the above objects, an embodiment of a method for forming a metal wiring in a semiconductor device, according to the present invention, may comprise the steps of: forming an interlevel dielectric layer over a semiconductor substrate; forming a metal layer on an upper surface of the interlevel dielectric layer; selectively etching the metal layer to form a plurality of metal lines having a gap therebetween; and forming a metal-insulating layer by filling the gap with an insulative material by a series of processes comprising (a) depositing the insulative material over and between the plurality of metal lines using a first high density plasma (HDP), (b) etching the deposited insulative material, and (c) depositing additional insulative material in the gap using a second HDP.

Preferably, the process of etching the insulative material of the present method comprises sputter etching. Further, the sputter etching process may include at least one sputtering gas selected from the group consisting of argon (Ar), oxygen (O₂) and helium (He), or a mixed gas of at least two members selected from the group consisting of argon (Ar), oxygen (O₂) and helium (He).

These and other aspects of the invention will become evident by reference to the following description of the invention, often referring to the accompanying drawings.

### BRIEF DESCRIPTION OF DRAWINGS

FIG. 1 illustrates a series of processes according to the conventional method for forming a metal wiring in a semiconductor.

FIG. 2 illustrates a problem where an overhang may occur during the conventional method shown in FIG. 1.

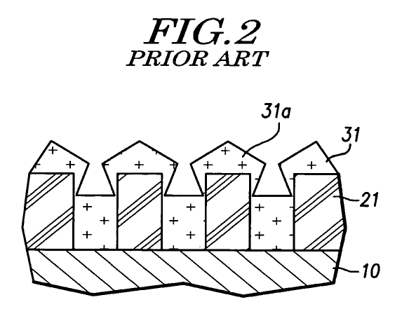

FIG. 3 illustrates an embodiment of a method for forming a metal wiring in a semiconductor device according to the present invention.

### DETAILED DESCRIPTION OF THE INVENTION

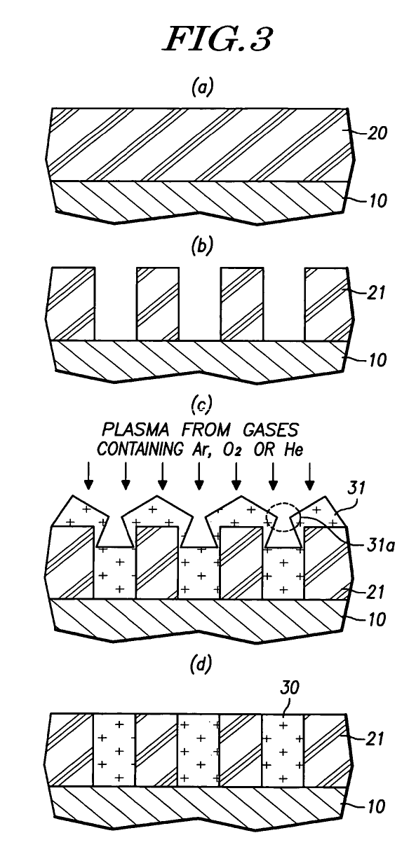

FIG. 3 illustrates a method for forming a metal wiring in a semiconductor device according to the present invention.

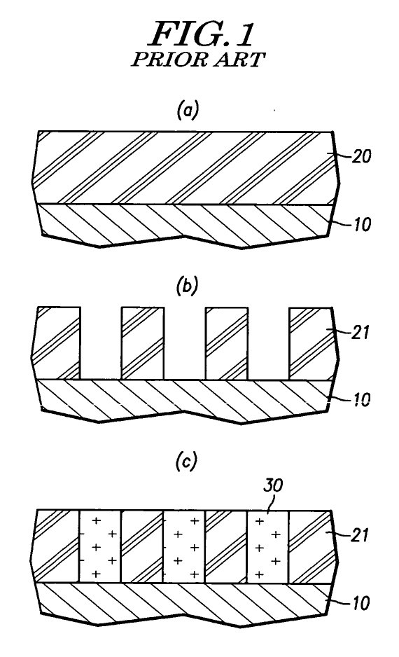

Several processes for forming a metal wiring, illustrated in steps (a) and (b) of FIG. 3, are similar to a conventional method. Namely, as shown in step (a) of FIG. 3, a metal layer 20 is formed on an upper surface of an interlevel dielectric layer 10 where via contacts may be formed in advance. The metal layer 20 may be similar to that of metal layer 20 in FIG. 1, and may further comprise an overlying layer of titanium (Ti), titanium nitride (TiN), or a bilayer of titanium (Ti) and titanium nitride (TiN) thereon. Then, as shown in step (b) of FIG. 3, a photoresist is coated on the metal layer 20, and exposed in a predetermined pattern. The exposed portion of the photoresist may be removed (alternatively, the unexposed portion of the photoresist, depending on whether the photoresist is positive or negative) to form a photoresist pattern. Subsequently, the metal layer 20 is etched by an etch process using the photoresist pattern as a mask so that a metal wiring including the plurality of metal lines 21 is completely formed.

Forming a metal-insulating layer in gaps between metal lines 21 using a HDP process is illustrated in step (c) of FIG. 3, in which one or more of the depositing, etching, and depositing processes are sequentially carried out.

According to a general HDP process, depositing and sputtering may be simultaneously performed, in order to prevent a void from forming inside the gaps because of a relatively rapid deposition of the insulative material at the top corner of metal lines 21. However, the gap may have a relatively narrow width (e.g., 0.2 μm or less, 0.15 μm or less, 0.12 μm or less, etc.) and a high aspect ratio (e.g., 2 or more, 2.5 or more, 3 or more, etc.), in certain high integration semiconductor device manufacturing processes. A conventional HDP process, which performs both depositing and sputtering at the same time, is not sufficient to prevent generation of the void in such high-integration processes.

The present invention includes an intermediate etching process step, which is preceded and followed by plasma depositing processes. In other words, depositing does not occur during the intermediate etching process. A variety of conventional methods, such as dry etching, wet etching (with a conventional gap fill insulator etchant, such as dilute aqueous HF or buffered HF [a so-called “buffered oxide etch” solution]), etc., can be adapted for the intermediate etching process.

The intermediate etching can be performed in a separate chamber other than the chamber where depositing is performed. It is preferable that sputtering etching by a HDP process is adapted (e.g., sputter etching with a high density plasma, in a conventional HDP deposition and/or etch chamber), because the sputter etch can be performed in the same chamber as for HDP depositing.

In the sputter etch process, a processing gas such as argon (Ar), oxygen (O₂), helium (He) or a mixture thereof, all of which are able to be changed to a plasma state, is injected into a processing chamber. When a high-frequency electric power is applied to the chamber, molecules in the processing gas may be changed to plasma. Then, plasmatic molecules of the processing gas travel perpendicularly to and collide with a semiconductor substrate placed on a stage of the chamber, thus enabling removal of an overhang portion 31a formed by the relatively rapid deposition of the insulative material 31. Here, a processing gas and applied electric power can be selected and/or controlled according to the amount of overhanging material to be etched. For example, helium (He), having a low atomic weight, needs a relatively high electric power, compared with argon (Ar). The advantage of helium (He) is that it can permeate more deeply than argon (Ar), in case the gap has a high aspect ratio.

It is difficult to control such intermediate etching to remove exactly only the overhang portion 31a. Namely, other portions of the deposited insulative material can also be etched during the intermediate etching process. However, this problem can be solved by an additional deposition after the intermediate etching. The main point is that the portion overly deposited during the first insulator material depositing step (i.e., the overhang portion 31a) can be removed by the intermediate etching process without depositing any insulator material. Preferably, a series of depositing, etching and depositing processes can be repeated once or several times before the metal-insulating layer 30 is completely formed.

Finally, as shown in step (d) of FIG. 3, a portion of the insulative material protruding over the metal lines 21 may be removed by a chemical mechanical polishing (CMP) step so that an upper surface of metal wiring is planarized. As a result, the metal-insulating layer 30 can be formed without a void. Alternatively, if a dielectric or insulator material is desired over the metal wiring 21, the final depositing step can be performed such that 1000-10,000 (preferably 3000-6000) Angstroms of the insulative material are formed over the metal wiring 21. A subsequent CMP step may be performed so that the upper surface of the insulative material is planarized. Furthermore, if another metal wiring is necessary, it can be formed by repetition of the above-explained steps, that is, a series of the steps of; forming an interlevel dielectric layer; forming a metal layer; forming a metal wiring; and forming a metal-insulating layer.

While the invention has been shown and described with reference to certain preferred embodiments thereof, it will be understood by those skilled in the art that various changes in form and details may be made therein without departing from the spirit and scope of the invention as defined by the appended claims.

What is claimed is:

1. A method for forming a metal wiring in a semiconductor device, comprising the steps of:
forming a metal layer on an upper surface of a dielectric layer on a semiconductor substrate;
selectively etching the metal layer to form a plurality of metal lines having a gap therebetween; and
forming a metal-insulating layer by filling the gap with an insulative material by a series of processes comprising (a) depositing the insulative material over and between the plurality of metal lines using a first high density plasma (HDP), (b) etching the deposited insulative material, and (c) depositing additional insulative material in the gap using a second HDP.

2. The method of claim 1, wherein etching the insulative material comprises sputter etching.

3. The method of claim 2, wherein the sputter etching uses at least one sputtering gas selected from the group consisting of argon (Ar), oxygen (O₂) and helium (He).

4. The method of claim 2, wherein the sputter etching uses a mixed gas comprising at least two members selected from the group consisting of argon (Ar), oxygen (O₂) and helium (He).

5. The method of claim 1, further comprising forming the interlevel dielectric layer on the semiconductor substrate.

6. A method for forming metal wiring, comprising the steps of:
forming a metal layer on an upper surface of a dielectric layer on a semiconductor substrate;
selectively etching the metal layer to form a plurality of metal lines, where adjacent metal lines have a gap therebetween;
high density plasma (HDP) depositing a first insulative material portion over and between the plurality of metal lines;
etching the deposited insulative material portion; and
HDP depositing a second insulative material portion thereon sufficiently to fill the gap(s).

7. The method of claim 6, wherein etching the insulative material portion comprises sputter etching.

8. The method of claim 7, wherein the sputter etching uses at least one sputtering gas selected from the group consisting of argon (Ar), oxygen (O₂) and helium (He).

9. The method of claim 7, wherein the sputter etching uses a mixed gas of at least two members selected from the group consisting of argon (Ar), oxygen (O₂) and helium (He).

10. The method of claim 6, further comprising forming the interlevel dielectric layer on the semiconductor substrate.
